(19) United States
(12) Patent Application Publication
(10) Pub. No.: US 2025/0275127 A1
(43) Pub. Date: Aug. 28, 2025

(54) SEMICONDUCTOR DEVICE AND METHOD THEREOF FOR INCREASING MISALIGNMENT MARGIN BETWEEN CONTACTS AND WIRING

(71) Applicant: MICRON TECHNOLOGY, INC., Boise, ID (US)

(72) Inventor: Miyuki Aohara, Higashihiroshima-shi (JP)

(73) Assignee: MICRON TECHNOLOGY, INC., Boise, ID (US)

(21) Appl. No.: 19/040,093

(22) Filed: Jan. 29, 2025

Related U.S. Application Data
(60) Provisional application No. 63/558,979, filed on Feb. 28, 2024.

(51) Int. Cl. H10B 12/00

(52) U.S. Cl. CPC H10B 12/50; H10B 12/09

(57) ABSTRACT

An apparatus includes a substrate; a memory cell array region on the substrate; a boundary region on the substrate surrounding the memory cell array region; a peripheral region on the substrate surrounding the boundary region; and a plurality of word lines extending in parallel across the memory cell array region, the boundary region, and the peripheral region. Each of the plurality of word lines has a first thickness in the memory cell array region and a second thickness thinner than the first thickness in the peripheral region.

CROSS-REFERENCE TO RELATED APPLICATION(S)

This application claims priority to U.S. Provisional Application No. 63/558,979, filed Feb. 28, 2024. The aforementioned application is incorporated herein by reference, in its entirety, for any purpose.

### BACKGROUND

Further miniaturization is being promoted in semiconductor memory devices, for example, semiconductor memory devices such as a dynamic random access memory (hereinafter referred to as DRAM) in order to increase the data storage capacity. For example, the repeating pitch size of wirings such as word lines of DRAM has been reduced, and the distance between the word lines has also been reduced. However, if a misalignment occurs with respect to word lines during formation of contact electrodes to be connected to the word lines, the contact electrodes may become open or short-circuited with adjacent word lines.

### BRIEF DESCRIPTION OF THE DRAWINGS

FIG. 1A is a plan view showing a schematic configuration of a semiconductor memory device according to an embodiment. FIG. 1B is a plan view showing a schematic configuration of a memory mat.

FIG. 2 is a plan layout diagram showing a schematic configuration of the semiconductor memory device according to the embodiment, and is an enlarged view of a memory mat end region A of FIG. 1B.

FIG. 3 is a plan layout diagram showing a schematic configuration of the semiconductor memory device according to the embodiment, and is an enlarged view of a memory mat end region B of FIG. 1B.

FIG. 4A and FIG. 4B are longitudinal-sectional views showing the schematic configuration of the semiconductor memory device according to the embodiment, and are diagrams showing the schematic configuration in an exemplary process stage subsequent to an exemplary process stage of FIG. 11A and FIG. 11B.

FIG. 5A and FIG. 5B are longitudinal-sectional views showing the schematic configuration of the semiconductor memory device according to the embodiment, and are diagrams showing the schematic configuration in the memory mat end region B of FIG. 1B.

FIG. 6 is a plan layout diagram showing a schematic configuration of a comparative example of the semiconductor memory device according to the embodiment, and is an enlarged view of a region corresponding to the memory mat end region A of FIG. 1B. FIGS. 7A and 7B are longitudinal-sectional views showing a schematic configuration of a comparative example of the semiconductor memory device according to the embodiment, and are diagrams corresponding to FIGS. 4A and 4B.

FIGS. 8A and 8B to FIGS. 15A and 15B are longitudinal-sectional views showing the semiconductor memory device according to the embodiment and a method for manufacturing the same, and are diagrams showing an example of the schematic configuration at the exemplary process stage in the order of steps.

FIG. 16 is a longitudinal-sectional view showing an example of an overall schematic configuration of the memory cell region of the semiconductor memory device according to the embodiment.

FIG. 17 is a circuit diagram showing a schematic configuration of an equivalent circuit of a memory cell of the semiconductor memory device according to the embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

Hereinafter, a semiconductor memory device 1 according to an embodiment and a method of manufacturing the same will be described with reference to the drawings. The semiconductor memory device 1 will be described by exemplifying DRAM. In the description of the embodiment, common or related elements or substantially the same elements are designated by the same or similar characters, and the description thereof will be omitted. In the figures, the dimensions and the dimensional ratios of respective parts in each figure do not necessarily match the dimensions and the dimensional ratios of the parts in the embodiment. The dimensions and dimensional ratios of the corresponding parts in the plan view and the longitudinal-sectional view do not necessarily match each other. A-A line, B-B line, C-C line and D-D line designate schematic positions of corresponding longitudinal-sectional diagrams. The up-and-down direction in the following description means an up-and-down direction when the semiconductor substrate 10 is placed on the lower side.

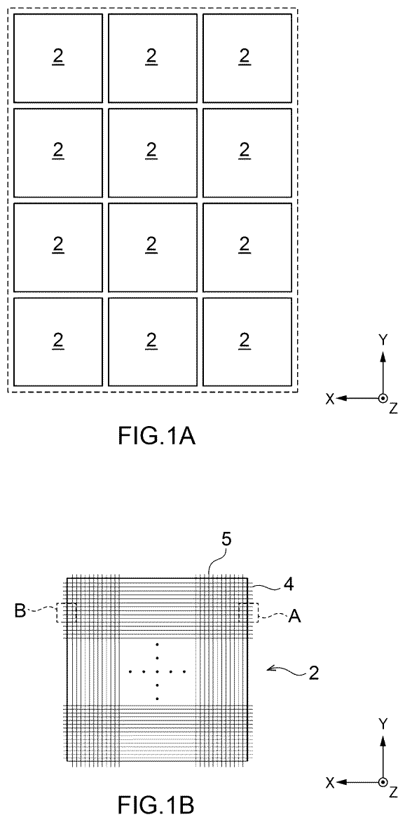

FIG. 1A and FIG. 1B are diagrams showing planar layouts of the semiconductor memory device 1 according to the embodiment. As shown in FIG. 1A, the semiconductor memory device 1 includes a plurality of memory mats 2 arranged in a matrix form on the surface of a semiconductor substrate. As shown in FIG. 1B, a plurality of word lines 4 are arranged in parallel on each memory mat 2 so as to extend in an X direction in the figures. Further, a plurality of bit lines 5 are arranged in parallel on the memory mat 2 so as to be orthogonal to the word lines 4, in other words, so as to extend in a Y direction in the figures. The direction parallel to the word lines 4, in other words, the X direction is referred to as a word line direction. The direction parallel to the bit lines 5, that is, the Y direction is referred to as a bit line direction.

Memory mat end regions A and B are arranged at a peripheral portion in the word line direction of the memory mat 2. The memory mat end region A is located at one end portion in the X direction of the memory mat 2, and the memory mat end region B is located at the other end portion in the X direction of the memory mat 2.

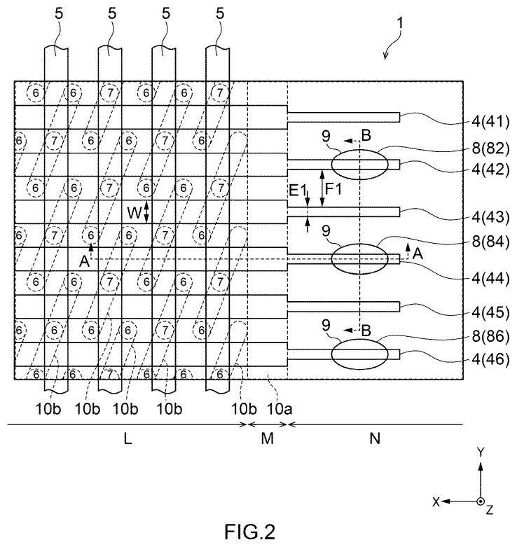

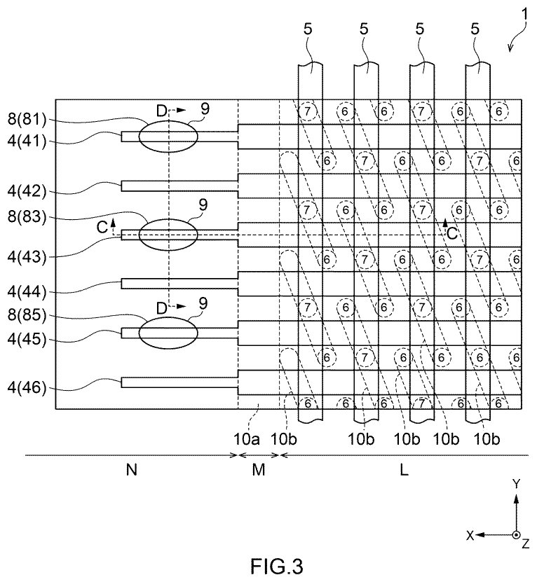

FIG. 2 is a plan view showing a schematic configuration in the memory mat end region A of FIG. 1B. FIG. 3 is a plan view showing a schematic configuration in the memory mat end region B of FIG. 1B. The planar layout shown in FIG. 3 is symmetrical to the planar layout shown in FIG. 2, and the other configurations are the same.

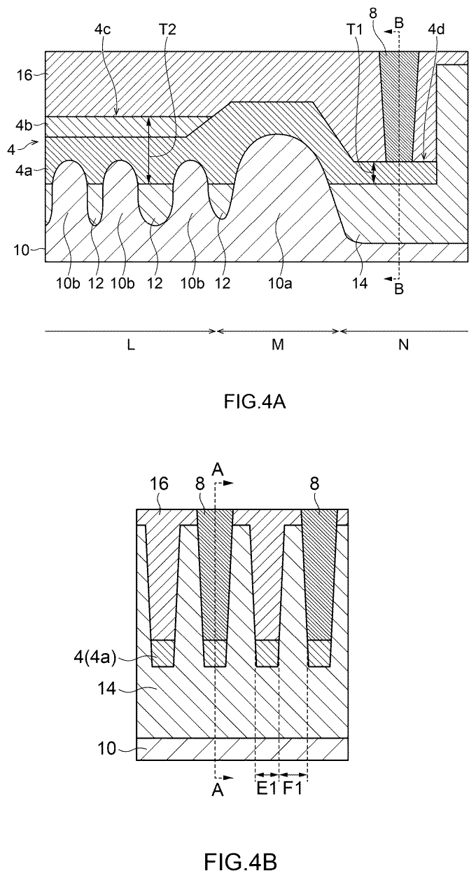

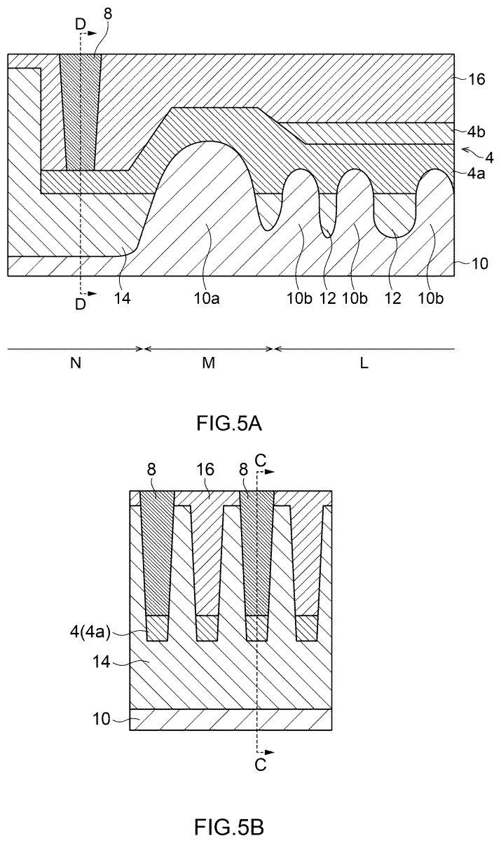

FIG. 4A is a longitudinal-sectional view showing a schematic configuration of a longitudinal-sectional view taken along A-A line of FIG. 2 and FIG. 4B. FIG. 4B is a longitudinal-sectional view showing a schematic configuration of a longitudinal-sectional view taken along B-B line of FIG. 2 and FIG. 4A. FIG. 5A is a longitudinal-sectional view showing a schematic configuration of a longitudinal-sectional view taken along C-C line of FIG. 3 and FIG. 5B. FIG. 5B is a longitudinal-sectional view showing a schematic configuration of a longitudinal-sectional view taken along D-D line of FIG. 3 and FIG. 5A.

The cross-sectional structure shown in FIG. 4A is symmetrical to the longitudinal-sectional structure shown in FIG. 5A, and both the structures are structures obtained by reversing them in the X direction except for the positions of word-line contacts 8. The cross-sectional structure shown in FIG. 4B has the same structure as the longitudinal-sectional structure shown in FIG. 5B except for the positions of the word-line contacts 8. Since the configurations in the memory mat end region A and the memory mat end region B are substantially the same in a planar structure and a cross-sectional structure, the configuration of the memory mat end region A will be described below.

As shown in FIG. 2, the semiconductor memory device 1 includes a memory cell array region L, a boundary region M, and a peripheral region N in the mat end region A. The boundary region M surrounds the periphery of the memory cell array region L, and the peripheral region N surrounds the periphery of the boundary region M. The boundary region M is adjacent to the memory cell array region L, the peripheral region N is adjacent to the boundary region M, and the boundary region M is sandwiched between the memory cell array region L and the peripheral region N. In the memory cell array region L, a plurality of word lines 4 arranged in parallel at equal intervals in the Y direction and a plurality of bit lines 5 arranged in parallel at equal intervals in the X direction are arranged orthogonally to each other. Active regions 10b each forming a memory cell are respectively arranged at the intersections between the word lines 4 and the bit lines 5. Each active region 10b has an island shape.

A peripheral insulating material 14 is provided in the peripheral region N, and peripheral circuits such as a row decoder and a row address buffer (not shown) are provided. The boundary region M is a region for separating the memory cell array region L and the peripheral region N from each other, and includes a boundary portion 10a extending in the Y direction. Each word line 4 is arranged so as to extend in the X direction across the memory cell array region L, the boundary region M, and the peripheral region N.

The longitudinal direction of the active regions 10b is inclined at a predetermined angle with respect to the bit lines 5. The word lines 4 function as gate electrodes of access transistors of the memory cells provided in the active regions 10b. The bit lines 5 are connected to the planar centers of the active regions 10b via bit-line contacts 7. In the active regions 10b, capacitance contacts 6 are arranged so as to sandwich the word lines 4 with respect to the bit-line contacts 7 of the bit lines 5. A capacitor (not shown) is connected to the capacitance contact 6.

The word line 4 is arranged so as to extend linearly from the memory cell array region L across the boundary region M and the peripheral region N. Word-line contacts 8 (82, 84, 86) which are electrically connected to word lines 4 (42, 44, 46) are provided in the peripheral region N. The word-line contacts 8 are connected to the word lines 4 at edge portions 9 of the word lines 4.

As shown in FIG. 3, in the memory mat end region B, word-line contacts 8 (81, 83, 85) are connected to word lines 4 (41, 43, 45) to which word-line contacts 8 are not connected in the memory mat end region A. The word-line contacts 8 (81, 83, 85) are connected to the word lines 4 (41, 43, 45) at the edge portions 9 of the word lines 4.

As shown in FIG. 2, in the peripheral region N of the memory mat end region A, the word-line contacts 8 are connected to every other word lines 4 (42, 44, 46). The word lines 4 (41, 43, 45) to which the word-line contacts 8 are not connected are arranged to be adjacent to the word lines 4 (42, 44, 46) to which the word-line contacts 8 (82, 84, 86) are connected.

As shown in FIG. 2, the word line 42 is sandwiched between the word line 41 and the word line 43. The word line 43 is sandwiched between the word line 42 and the word line 44. The word line 44 is sandwiched between the word line 43 and the word line 45. The word line 45 is sandwiched between the word line 44 and the word line 46. A plurality of word lines 4 (41 to 46) are arranged in order as described above, and are arranged in such a way that this order is repeated thereafter.

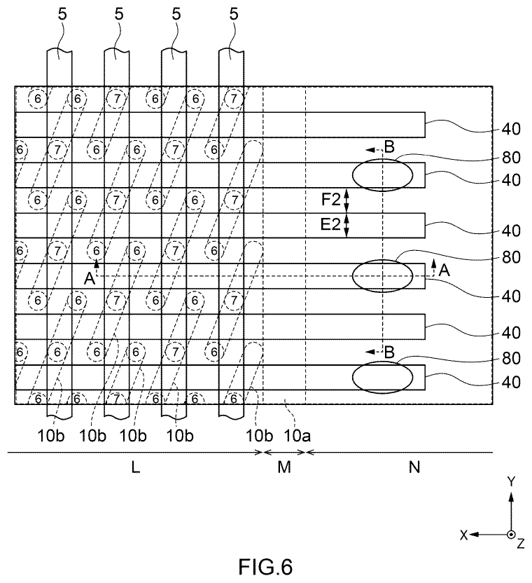

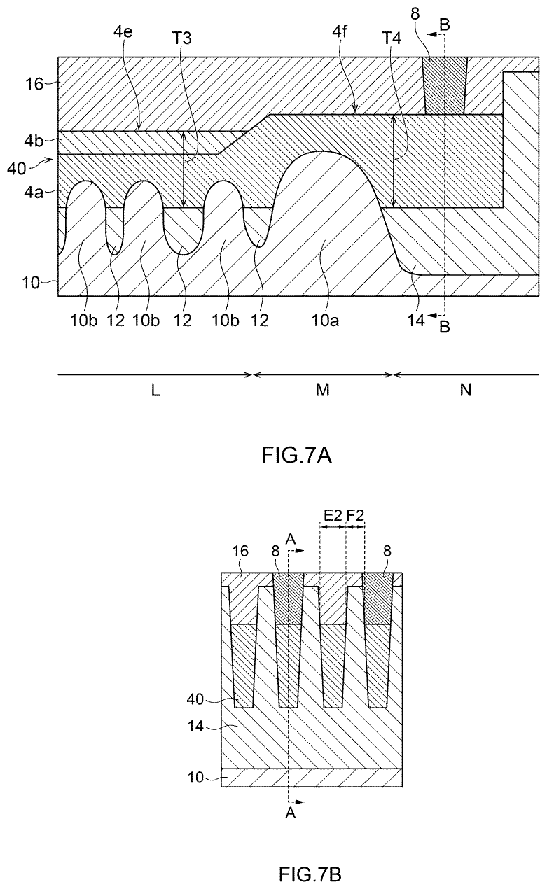

FIG. 6, FIG. 7A, and FIG. 7B are diagrams showing comparative examples for comparing the configuration of the semiconductor memory device 1 according to the embodiment. FIG. 6 corresponds to FIG. 2, and FIGS. 7A and 7B correspond to FIGS. 4A and 4B.

As shown in FIG. 4A and FIG. 4B, in the semiconductor memory device 1 according to the embodiment, the thickness T1 of the word lines 4 in the peripheral region N is smaller than the thickness T2 of the word lines 4 in the memory cell array region L. In other words, in the semiconductor memory device 1 according to the embodiment, the height positions 4d of the top surfaces of the word lines 4 in the peripheral region N are lower than the height positions 4c of the top surfaces of the word lines 4 in the memory cell array region L. The height positions 4c and 4d of the top surfaces of the word lines 4 are defined by distances from an arbitrary reference position. The height positions 4c and 4d of the top surfaces of the word lines 4 are defined, for example, by the distance from the bottom surface of the semiconductor substrate 10 to the top surfaces of the word lines 4. The same applies to the height positions 4e and 4f of the top surfaces described later. Further, in the boundary region M, the word line 4 includes a bulged portion whose top surface is higher than those in the memory cell array region L and the peripheral region N. Further, the bottom surface of each word line 4 in the memory cell array region L is at a substantially same level as that in the peripheral region N.

On the other hand, as shown in FIGS. 7A and 7B, in the comparative structure, the thickness T4 of word lines 40 in the peripheral region N is larger than the thickness T3 of word lines 40 in the memory cell array region L. In other words, in the comparative structure, the height position 4f of the top surfaces of the word lines 40 in the peripheral region N is higher than the height position 4e of the top surfaces of the word lines 40 in the memory cell array region L.

As shown in FIG. 4B and FIG. 7B, the cross-sectional shape of the word line 4 is an inverted tapered shape in the longitudinal-sectional view. Here, the inverted tapered shape means a shape that gradually becomes thicker toward the upper side thereof. Therefore, the width of the word line 4 is smaller at the lower portion thereof than that at the upper portion thereof. In the peripheral region N, the word lines 4 shown in FIG. 4B correspond to the lower portions of the word lines 40 shown in FIG. 7B. Therefore, the widths El of the word lines 4 shown in FIG. 2 and FIG. 4B are smaller than the widths E2 of the word lines 40 shown in FIG. 6 and FIG. 7B. Further, the distance Fl between adjacent word lines 4 shown in FIG. 2 and FIG. 4B is larger than the distance F2 between adjacent word lines 40 shown in FIG. 6 and FIG. 7B. As the distance between the adjacent word lines is larger, the possibility that a word-line contact and a word line adjacent thereto are short-circuited is reduced. For example, as the distance between the word-line contact 82 and the word line 43 adjacent thereto is larger, the possibility that the word-line contact 82 and the word line 43 adjacent thereto are short-circuited to each other is reduced. In other words, as shown in FIG. 2 and FIG. 4B, the misalignment margin of the word-line contact 8 of the semiconductor memory device 1 according to the embodiment is larger than the misalignment margin of the word-line contact 80 of the comparative structure shown in FIG. 6 and FIG. 7B.

Furthermore, as shown in FIG. 2, the widths El of the word lines 4 in the peripheral region N are smaller (slenderer) than the widths W of the word lines 4 in the memory cell array region L.

In the semiconductor memory device 1 according to the embodiment, the distance between the word-line contact 8 and the word line 4 adjacent thereto is large. Therefore, it is possible to increase the misalignment margin between the word-line contact 8 and the word line 4, so that even if the word-line contact 8 is misaligned, short-circuits with adjacent word lines 4 can be avoided or suppressed. Therefore, the manufacturing yield of the semiconductor memory device 1 can be improved.

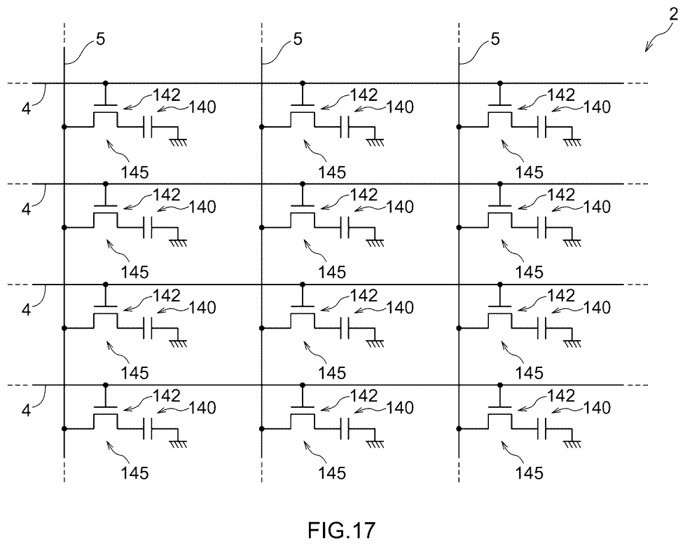

FIG. 17 is a longitudinal-sectional view showing an example of the overall schematic configuration of the memory cell region of the semiconductor memory device according to the embodiment. As shown in FIG. 17, a semiconductor substrate 112, a shallow trench isolation 124, an access transistor 142, a capacitance contact 116, etc. included in a memory cell 145 of DRAM are provided below the capacitor 140. The capacitor 140 is provided on the semiconductor substrate 112 on which the shallow trench isolation 124, the access transistor 142, the capacitance contact 116, etc. are formed. The semiconductor substrate 112 corresponds to the semiconductor substrate 10 described later.

A lower electrode of the capacitor 140 shown in FIG. 17 is electrically connected to one of the source and drain regions of the access transistor 142 formed in the active region of the semiconductor substrate 112 via the capacitance contact 116. The lower electrode of the capacitor 140 is connected to the semiconductor substrate 112. The gate electrodes of the access transistors 142 correspond to the word lines 4 in FIG. 1B, FIG. 2, FIG. 3, etc.

As shown in FIG. 17, an upper layer portion including multilevel upper wiring layers such as wirings 148, 149, 150, and 151, etc. is provided above the capacitor 140. The upper layer portion is arranged above the memory cell 145. An upper electrode of the capacitor 140 is arranged on the multilevel upper wiring layer side of the wirings 148, 149, 150, and 151, etc. Elements 146, 147, and 152 shown in FIG. 17 include insulating materials.

Above the diagrams shown in FIGS. 4A and 4B, the capacitors 140 and the upper layer portions are provided as in the case of the configuration shown in FIG. 17.

FIG. 17 shows an equivalent circuit of the memory cell array of the semiconductor memory device according to the embodiment. The plurality of memory cells 145 are arranged in a matrix form with being connected to the intersections between the plurality of word lines 4 and the plurality of bit lines 5 which are arranged orthogonally to each other. One memory cell 145 includes a pair of an access transistor 142 and a capacitor 140.

The access transistor 142 includes, for example, a metal-oxide-semiconductor field-effect transistor (MOSFET). The gate electrode of the access transistor 142 functions as the word line 4 of DRAM. The word line 4 functions as a control line for controlling the selection of the corresponding memory cell. One of the source and drain of the access transistor 142 is connected to the bit line 5, and the other is connected to the capacitor 140. The capacitor 140 includes a capacitor, and data is stored by accumulating an electric charge in the capacitor.

During data writing into the memory cell 145, a potential for turning on the access transistor 142 is applied to the word line 4, and a low potential or a high potential which corresponds to write data “0” or “1” is applied to the bit line 5. During data reading from the memory cell 145, a potential for turning on the access transistor 142 is applied to the word line 4. As a result, the potential extracted from the capacitor 140 to the bit line 5 is sensed by a sense amplifier connected to the bit line 5, whereby the data is determined.

A first manufacturing method for the semiconductor memory device according to the embodiment will be described with reference to FIGS. 8A and 8B to FIGS. 11A and 11B and FIGS. 4A and 4B. FIGS. 8A, 8B to FIGS. 11A, 11B and FIGS. 4A, 4B are diagrams showing the schematic structure of the memory mat end region A of FIG. 2 in the order of steps.

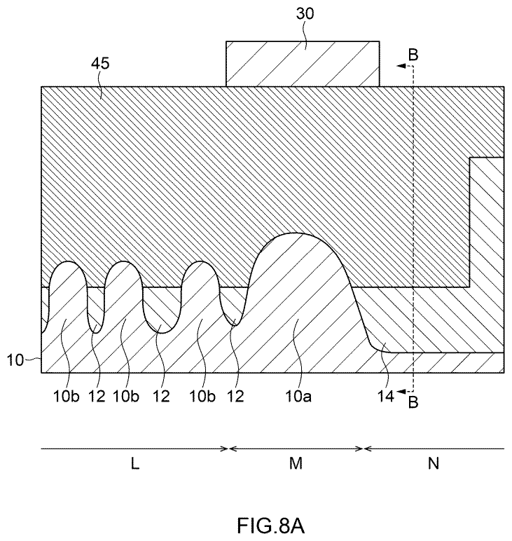

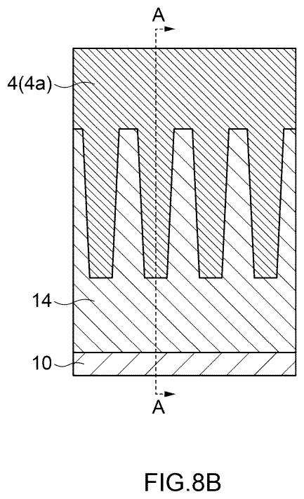

As shown in FIG. 8A and FIG. 8B, isolations 12 and a peripheral insulating material 14 are formed on the semiconductor substrate 10, and a conductive material for forming the word lines 4 is formed. The semiconductor substrate 10 includes, for example, a silicon single crystal substrate. The isolations 12 and the peripheral insulating material 14 are formed by forming trenches in the semiconductor substrate 10 and embedding an insulating material containing silicon nitride (SIN), silicon dioxide (SiO₂), etc. in the trenches. This insulating material is formed, for example, by chemical vapor deposition (hereinafter referred to as “CVD”). Next, trenches for forming the word lines 4 are formed, and a conductive material 45 containing, for example, titanium nitride (TiN), etc. is embedded in the trenches.

The trenches for forming the word lines 4 are formed by forming a photoresist mask using, for example, a well-known lithography technique, and then performing anisotropic dry etching. At this time, the trenches for forming the word lines 4 have inverted tapered shapes. The conductive material 45 formed in the trenches for forming the word line 4 is formed, for example, by CVD. Next, a photoresist 30 is formed on the conductive material 45 in the boundary region M. The photoresist 30 is formed by using the well-known lithography technique. The photoresist 30 is not formed above the memory cell array region L and the peripheral region N, so that the top surfaces of the memory cell array region L and the peripheral region N are exposed.

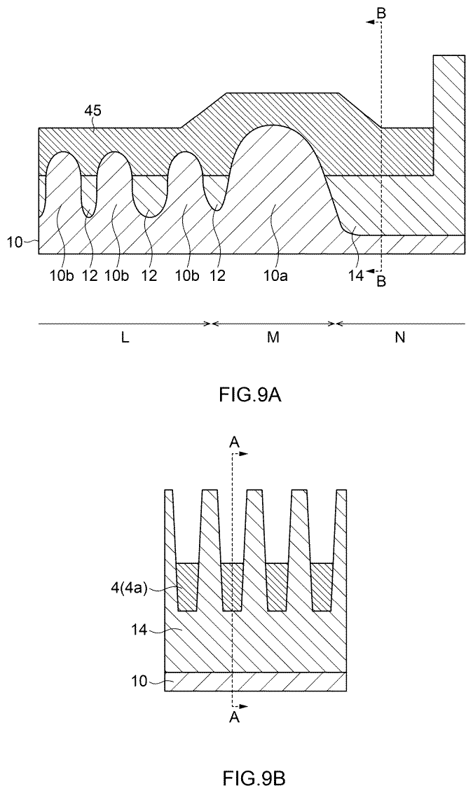

Next, as shown in FIG. 9A and FIG. 9B, dry etching is performed on the conductive material 45 by using the photoresist 30 as an etching mask to reduce the thickness of the conductive material 45 in the memory cell array region L and the peripheral region N which are not covered with the photoresist 30. Next, the photoresist 30 is removed, and dry etching is performed on the conductive material 45 until the thickness of the conductive material 45 reaches a desired thickness. This dry etching is performed under a condition in which the etching rate of the conductive material 45 is higher than the etching rate of silicon dioxide contained in the peripheral insulating material 14. The dry etching may be anisotropic or isotropic etching.

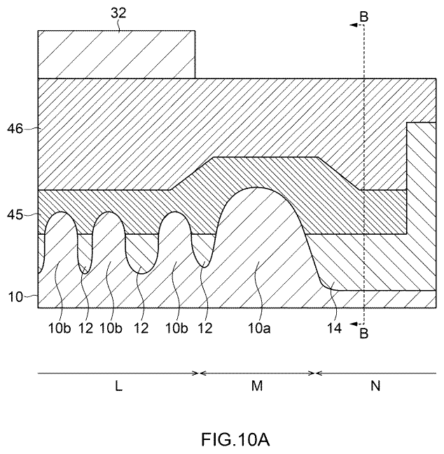

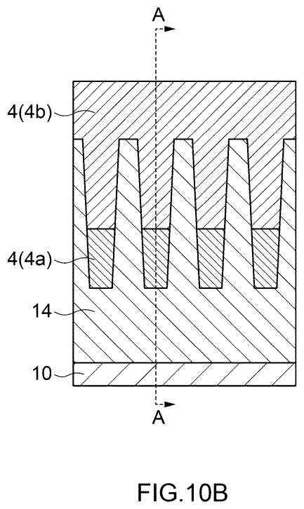

Next, as shown in FIG. 10A and FIG. 10B, a conductive material 46 containing polysilicon doped with impurities such as phosphorus is formed so as to cover the top surfaces of the conductive material 45 and the peripheral insulating material 14. The conductive material 46 is formed, for example, by CVD. Next, a photoresist 32 is formed on the conductive material 46 in the memory cell array region L. The photoresist 32 is formed by using the well-known known lithography technique.

Next, dry etching is performed on the conductive material 46 by using the photoresist 32 as an etching mask to remove the conductive material 46 in the boundary region M and peripheral region N. The dry etching may be anisotropic or isotropic dry etching. Next, the photoresist 32 is removed, and etching is performed on the conductive material 46 until the conductive material 46 in the memory cell array region L has a desired thickness. This etching is performed under a condition in which the etching rate of the conductive material 46 is higher than the etching rate of the conductive material 45.

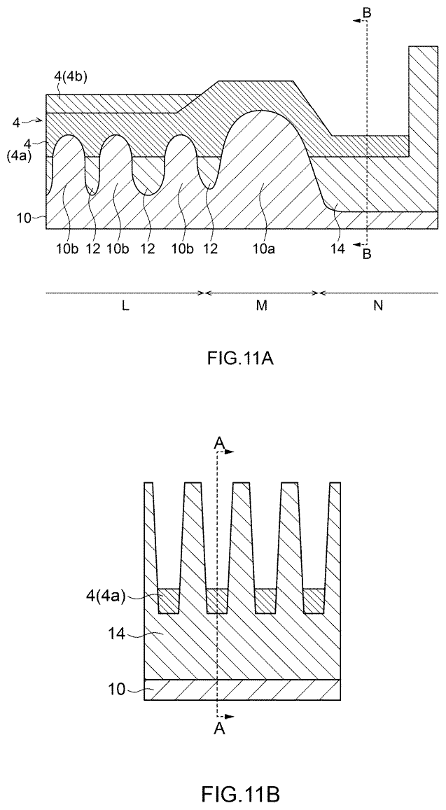

Next, etching is performed on the conductive material 45 to reduce the thickness of the conductive material 45 in the peripheral region N. This etching is performed under a condition in which the etching rate of the conductive material 45 is higher than the etching rate of the conductive material 46. In this etching, a wet etching solution containing, for example, hydrochloric hydrogen peroxide mixture (HPM, a mixture of HCl, H₂O₂, and H₂O) can be used. The remaining conductive material 45 becomes first layers 4a of the word lines 4, and the conductive material 46 becomes second layers 4b of the word line 4. Through the above step, a structure shown in FIG. 11A and FIG. 11B is formed. Through this step, only the lower portions of the inverted tapered word lines 4 remain in the peripheral region N, so that the widths of the word lines 4 in the peripheral region N becomes smaller.

Next, as shown in FIG. 4A and FIG. 4B, an insulating film 16 is formed so as to cover the word lines 4 and the peripheral insulating material 14, and then the word-line contacts 8 which reach the word lines 4 in the peripheral region N are formed. The insulating film 16 includes an insulating material such as silicon dioxide, etc. and is formed, for example, by CVD. The word-line contacts 8 are plug electrodes that penetrate from the surface of the insulating film 16 to the top surfaces of the word lines 4, and include, for example, a conductive material such as tungsten, etc. Through the above steps, the semiconductor memory device 1 according to the embodiment is formed.

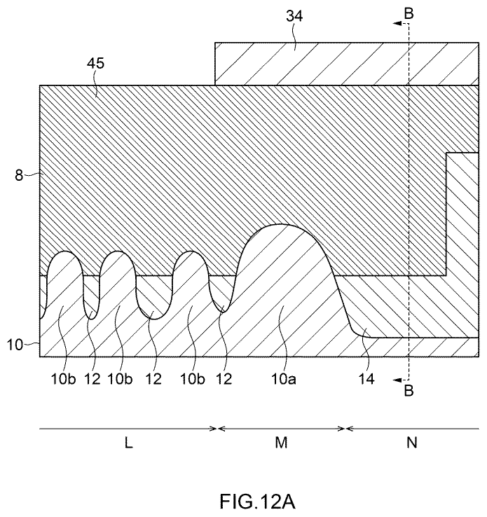

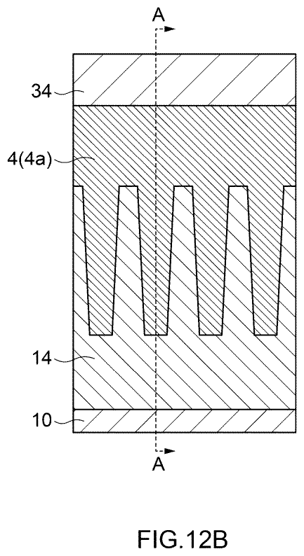

Next, a second manufacturing method for the semiconductor memory device according to the embodiment will be described with reference to FIG. 12A and 12B to FIG. 15A and 15B, FIG. 11A and 11B, and FIG. 4A and 4B.

First, a structure shown in FIG. 12A and FIG. 12B is formed. The structure shown in FIG. 12A and FIG. 12B is substantially the same as the structure shown in FIG. 8A and FIG. 8B in the description of the first manufacturing method, and differ in the formation region of the photoresist 34. The photoresist 34 is formed on the conductive material 45 in the boundary region M and the peripheral region N. The photoresist 34 is formed by using the well-known lithography technique.

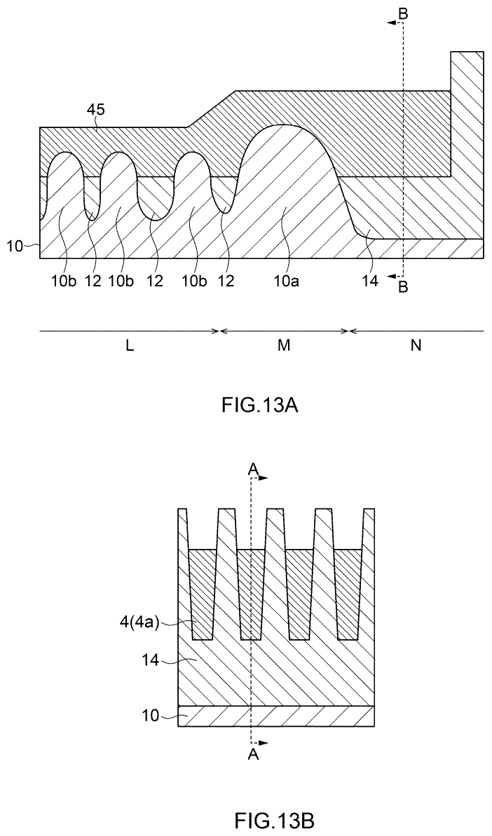

Next, as shown in FIG. 13A and FIG. 13B, dry etching is performed on the conductive material 45 by using the photoresist 34 as an etching mask to reduce the thickness of the conductive material 45 in the memory cell array area L which is not covered with the photoresist 34. This dry etching may be anisotropic or isotropic dry etching. Next, the photoresist 34 is removed to expose the top surface of the conductive material 45, and then dry etching is performed on the conductive material 45 until the thickness of the conductive material 45 reaches a desired thickness. This dry etching is performed under a condition in which the etching rate of the conductive material 45 is higher than the etching rate of silicon dioxide contained in the peripheral insulating material 14. This dry etching may be anisotropic or isotropic dry etching.

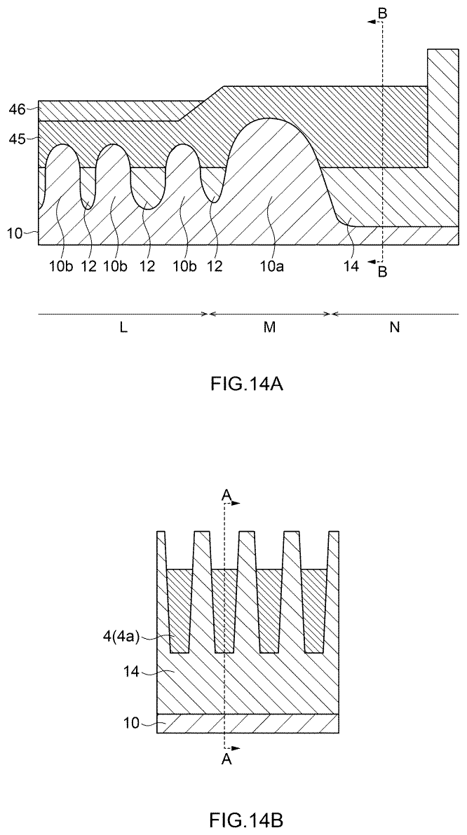

Next, as shown in FIG. 14A and FIG. 14B, a conductive material 46 containing polysilicon doped with impurities such as phosphorus is formed so as to cover the conductive material 45 and the peripheral insulating material 14, and then the conductive material 46 is caused to remain only in the memory cell array region L by performing etch-back on the entire surface of the conductive material 46. The conductive material 46 is formed, for example, by CVD. Dry etching can be used for the etch-back, and it may be anisotropic or isotropic dry etching. This dry etching is performed under a condition in which the etching rate of the conductive material 46 is higher than the etching rates of the silicon dioxide contained in the peripheral insulating material 14 and the conductive material 45.

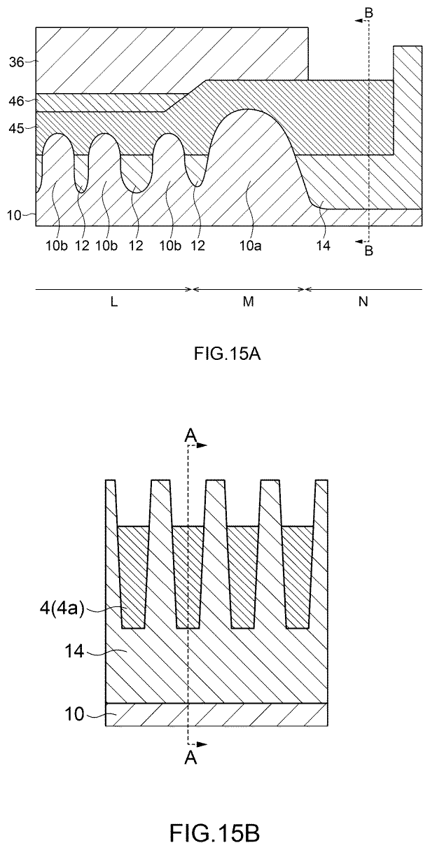

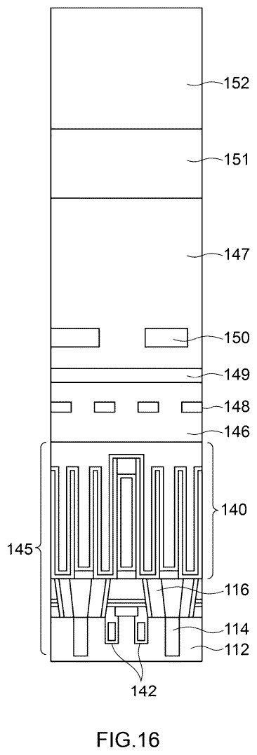

Next, as shown in FIG. 15A and FIG. 15B, a photoresist 36 is formed on the conductive material 45 and the conductive material 46 in the memory cell array region L and the boundary region M. The photoresist 36 is formed by using a well-known lithography technique.

Next, dry etching is performed on the conductive material 45 in the peripheral region N by using the photoresist 36 as an etching mask until the thickness of the conductive material 45 reaches a desired thickness, thereby reducing the thickness of the conductive material 45. This etching is performed under a condition in which the etching rate of the conductive material 45 is higher than the etching rate of silicon dioxide contained in the peripheral insulating material 14. The dry etching may be anisotropic or isotropic dry etching. Next, the photoresist 36 is removed. Through the above step, the structure shown in FIG. 11A and FIG. 11B is formed. This step reduces the widths of the word lines 4 in the peripheral region N.

Next, as shown in FIG. 4A and FIG. 4B, the insulating film 16 and the word-line contacts 8 are formed. This manufacturing process is the same as the process described in FIG. 4A and FIG. 4B of the first manufacturing method. Through the above steps, the semiconductor memory device 1 according to the embodiment is formed.

As described above, the semiconductor memory device 1 according to the embodiment has been described by exemplifying DRAM. However, this is an example and is not intended to be limited to DRAM. As the semiconductor memory device 1, memory devices other than DRAM, for example, memory devices such as a static random access memory (SRAM), a flash memory, an erasable programmable read only memory (EPROM), a magneto-resistive random access memory (MRAM), and a phase-change memory, etc. may be applied.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate;
a memory cell array region on the substrate;
a boundary region on the substrate surrounding the memory cell array region;
a peripheral region on the substrate surrounding the boundary region; and
a plurality of word lines extending in parallel across the memory cell array region, the boundary region, and the peripheral region;
wherein each of the plurality of word lines has a first thickness in the memory cell array region and a second thickness thinner than the first thickness in the peripheral region.

2. The apparatus of claim 1, wherein each of the plurality of word lines has a bulged portion in the boundary region.

3. The apparatus of claim 1, wherein a bottom surface of each of the plurality of word lines in the memory cell array region is at a substantially same level as that in the peripheral region.

4. The apparatus of claim 1, wherein a top surface of each of the plurality of word lines in the memory cell array region is at a higher level than that in the peripheral region.

5. The apparatus of claim 4, wherein a top surface of each of the plurality of word lines in the boundary region is at a higher level than that in the memory cell array region.

6. The apparatus of claim 1, wherein the plurality of word lines are arranged with the same intervals.

7. The apparatus of claim 1, wherein each of the plurality of word lines includes conductive material embedded in a trench of the substrate.

8. The apparatus of claim 1, further comprising a plurality of plugs each electrically connected to a corresponding one of the plurality of word lines at the peripheral region.

9. The apparatus of claim 1, wherein a width of each of the plurality of word lines in the peripheral region is smaller than that in the memory cell array region.

10. The apparatus of claim 1, wherein each of the plurality of word lines in the memory cell array region comprises a first layer and a second layer on the first layer.

11. The apparatus of claim 10, wherein each of the word lines in the peripheral region comprises the first layer and is free from the second layer.

12. An apparatus comprising:
a substrate;
a memory cell array region on the substrate;
a boundary region on the substrate surrounding the memory cell array region;
a peripheral region on the substrate surrounding the boundary region; and
a plurality of word lines extending in parallel across the memory cell array region, the boundary region, and the peripheral region;
wherein a top surface of each of the plurality of word lines in the memory cell array region is higher than that in the peripheral region.

13. The apparatus of claim 12, wherein each of the plurality of word lines has a bulged portion in the boundary region.

14. The apparatus of claim 12, wherein a bottom surface of each of the plurality of word lines in the memory cell array region is at a substantially same level as that in the peripheral region.

15. The apparatus of claim 14, wherein a top surface of each of the plurality of word lines in the boundary region is at a higher level than that in the memory cell array region.

16. The apparatus of claim 12, wherein the plurality of word lines are arranged with the same intervals.

17. The apparatus of claim 12, further comprising a plurality of plugs each electrically connected to a corresponding one of the plurality of word lines at the peripheral region.

18. The apparatus of claim 12, wherein a width of each of the plurality of word lines in the peripheral region is smaller than that in the memory cell array region.

19. The apparatus of claim 12, wherein each of the plurality of word lines in the memory cell array region comprises a first layer and a second layer on the first layer.

20. The apparatus of claim 19, wherein each of the word lines in the peripheral region comprises the first layer and is free from the second layer.
